(19) United States
(12) Patent Application Publication
(10) Pub. No.: US 2007/0096333 A1
(43) Pub. Date: May 3, 2007

(54) Optimal stacked die organization

(76) Inventors: Amir Motamedi, Munchen (DE); Hermann Ruckerbauer, Moos (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/263,412

(22) Filed: Oct. 31, 2005

(51) Int. Cl. H01L 23/52

(52) U.S. Cl. 257/777

(57) ABSTRACT

A multi-chip package and method is disclosed. In one embodiment, the multi-chip package includes at least four of spaced semiconductor integrated circuit chips mounted on a printed circuit board, consisting of the first pair of the semiconductor integrated circuit chips and the second pair of the semiconductor integrated circuit chips. The chips of the first pair of the semiconductor integrated circuit chips are arranged substantially parallel and the chips of the semiconductor integrated circuit chips of the second pair are arranged substantially stacked over the chips of the first pair of the semiconductor integrated circuit chips.

### FIELD OF THE INVENTION

The present invention relates generally to stacked semiconductor device assemblies and packages, as well as to associated assembly and packaging methods. More particularly, the invention pertains to multi-chip assemblies and packages with good thermal properties and dense chip packaging.

### BACKGROUND

The dimensions of many different types of state of the art electronic devices are ever decreasing. To reduce the dimensions of electronic devices, the structures by which the microprocessors, memory devices, other semiconductor devices, and other electronic components of these devices are packaged and assembled with carriers, such as circuit boards, must become more compact. In general, the goal is to economically produce a chip-scale package (CSP) of the smallest size possible, and with conductive structures, such as leads, pins, or conductive bumps, which do not significantly contribute to the overall size in the X, Y, or Z dimensions, all while maintaining a very high performance level.

Conventionally, semiconductor device packages have been multilayered structures having one, two or more chips stacked above each other. The major problems of such systems are of thermal nature since it was not possible to dissipate the heat efficiently in these systems. Further problems are also signal falsification and wiring problems. One example of the state of the art is given in FIG. 1. In this example four chips are stacked above each other to form a package, so that this arrangement will also be referred to as a one-four-stack arrangement. The disadvantage of this package is very poor heat dissipation, long signal routes, possible inter-crossing of the connections, routing problems and cross talk. A further disadvantage of the package as shown in FIG. 1 is the elevation of the entire package.

Furthermore, WO 96/13855 discloses an arrangement in which two chips are provided on the opposite sides of a lead plate.

For these and other reasons there is a need for the present invention.

Following terms will be used in following:

The semiconductor integrated circuit chip will be in following referred to as a “chip”;

In the packaging process a chip may also be referred to as a “die”;

The term stacked means an arrangement where two objects are placed above each other;

“stacked in parallel” means that the chips are stacked essentially exactly above each other, wherein a top surface of one chip is facing a bottom surface of the chip arranged above it;

“stacked anti parallel” means that the chips are stacked essentially exactly above each other, wherein a top surface of one chip is facing a top surface of the chip arranged above it or wherein a bottom surface of one chip is facing a bottom surface of the chip arranged above it;

“a bottom surface of a chip” is a surface which is closer to the printed circuit board; the bottom surface is also the surface of the chip which is provided with pads connected to the printed circuit board. “a top surface of a chip” is a surface opposite to the bottom surface.

### SUMMARY

The present invention provides a multi-chip package and method of making a multi-chip package. In one embodiment, the multi-chip package includes at least four of spaced semiconductor integrated circuit chips mounted on a printed circuit board, consisting of the first pair of the semiconductor integrated circuit chips and the second pair of the semiconductor integrated circuit chips. The chips of the first pair of the semiconductor integrated circuit chips are arranged substantially parallel and the chips of the semiconductor integrated circuit chips of the second pair are arranged substantially stacked over the chips of the first pair of the semiconductor integrated circuit chips.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a cross view example of a multi-chip package assembly according to the prior art.

FIG. 2 illustrates a cross view example of a multi-chip package assembly according of the present invention.

FIGS. 3-5 illustrate various examples of a multi-chip package of the present invention when attached to a printed circuit board and some processes in their manufacturing.

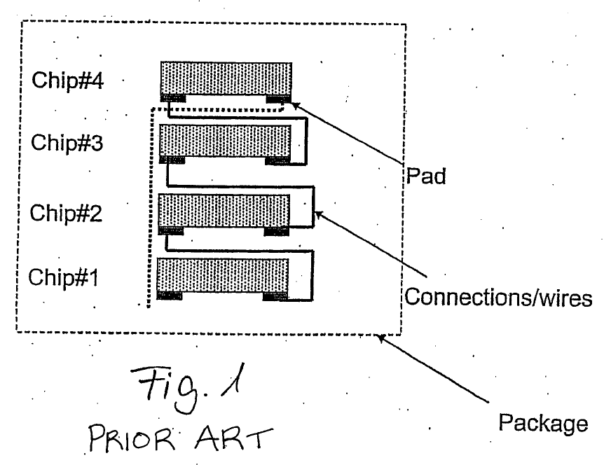

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention provides higher density organization of a plurality of semiconductor integrated circuit chips wherein the semiconductor integrated circuit chips are arranged such that good thermal properties and short signal times can be achieved.

The present invention also provides an assembly which effectively dissipates heat generated during normal operation. Efficient thermal management increases the operational life of the module, and improves reliability by eliminating the effects of elevated temperature on the electrical characteristics of the integrated circuit and packaging. When packages are not stacked, heat from the embedded integrated circuits, generated through normal operation, is primarily dissipated by convection from the package's external surfaces to the surrounding air. When modules are formed by stacking packages, the buried packages have reduced surface area exposed to the air so that the heat dissipation is reduced.

According to the present invention, a multi-chip package and interconnect assembly is provided which allows short interconnection between chips as well as good heat conduction from the chips to the package exterior. The transit time of signals between chips is typically about 30-40% than less that of using individual packages. Furthermore, heat generated during the operation of the chip can be efficiently dissipated. According to one embodiment of the present invention there are provided two stacks of chips, wherein each stack consists of two chips and not of four as in the prior art. Even though the surface of the arrangement is somewhat increased, due to the possibility to arrange a heat sink in between the chips and to connect the chips in a much shorter manner, the arrangement of the present invention is superior to the one of the prior art. The two-two-stack-arrangement of the invention enables a better signal properties than the one-four-stack of the prior art. The routing between the chips can further be optimized by providing a simpler pin allocation so that it is possible to completely avoid the wiring intercrossing.

In one embodiment, the present invention provides a package having at least four chips wherein the four chips are divided into the first pair of chips and the second pair of chips, wherein the first pair of chips are arranged essentially in parallel in the XY plane and second two pair of chips are stacked in parallel or anti-parallel with regard to the first pair of chips. It is to be noted that the reference to the XYZ-planes is only for the purpose of describing the special arrangement of the chips is not intended to be limiting for the arrangement of the present invention. For the purposes of simplicity XY plane will be regarded as the plane of the portion of the printed circuit board onto which two chips are provided.

In one embodiment, between the first pair of chips and/or the second pair of chips at least one heat sink is provided which is thermally connected to at least the first and/or the second pair of chips.

In another embodiment a single heat sink is provided, which is arranged between the first and the second pair of chips, wherein the heat sink is thermally connected to both the first and the second pair of chips.

In a preferred embodiment of the invention a first and a second heat sink are provided, wherein the first heat sink is thermally connected to the first and the second heat sink is thermally connected to the second pair of chips.

In a preferred embodiment of the invention the packaging of the chip are preformed in a ball grid arrays design, which are used to connect the package to a printed circuit board (PCB).

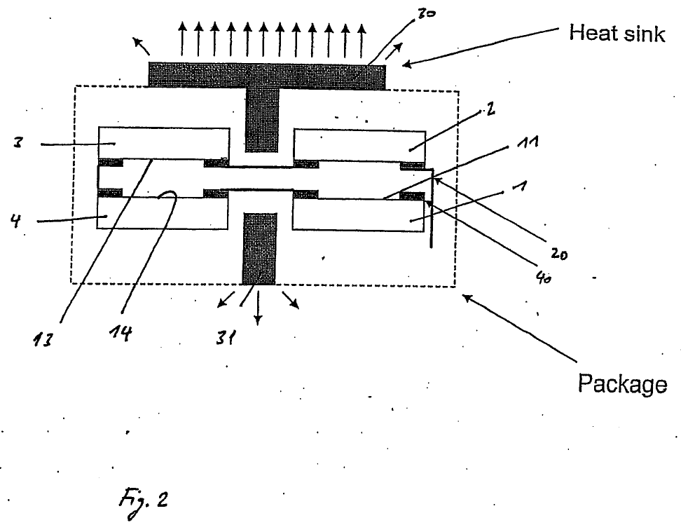

Turning now to the figures and, more particularly, FIG. 2 illustrates a cross view example of a first embodiment with multi-chip package assembly 100 according to the present invention.

As it can be seen from FIG. 2, chip 1 and chip 4 form the first pair of chips, and chip 2 and chip 3 form the second pair of chips. The same applies throughout the description of the Figures.

According to FIG. 2, the second pair of chips is stacked above the first pair of chips in an anti-parallel above each other. In the anti-parallel manner means in this case the top surface 11 of chip 1 for example is viewing the top surface 12 of chip 2. The same applies to the top surface 13 of chip 3 and the top surface 14 of chip 4.

Chips 1, 2, 3 and 4 are interconnected by means of wiring means 20, which connect pads 40 of chips 1,2,3 and 4. Between chips 2 and 3 as well as between chips 1 and 4 heat sinks 30 and 31 are provided.

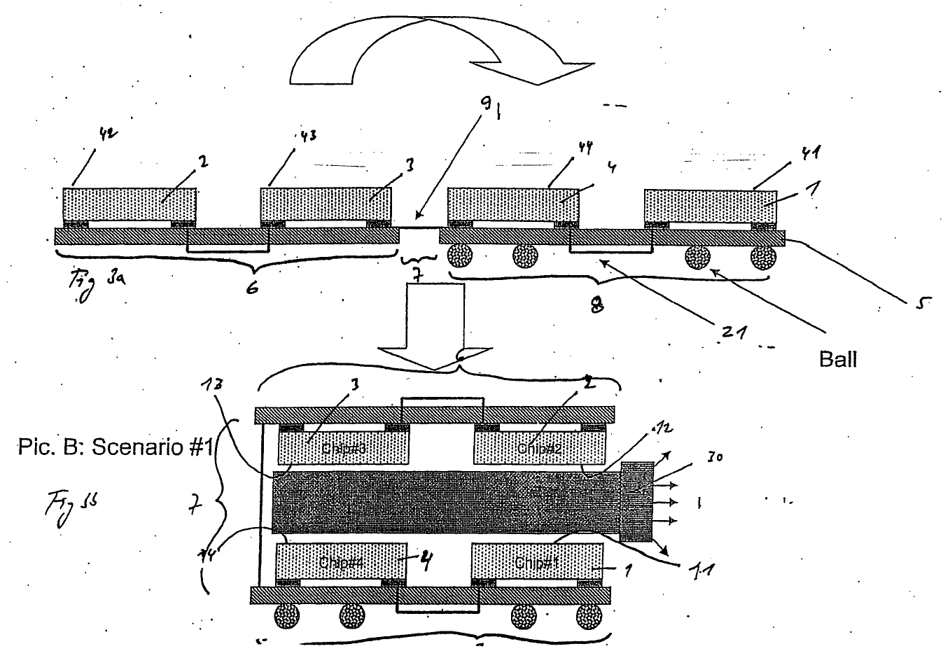

FIGS. 3a and 3b illustrate one preferred embodiment of the present invention. In this embodiment chips 1,2,3 and 4 are arranged in such a way that all four chips are in a thermal contact with heat sink 30. A method of manufacturing the arrangement of FIG. 3b is schematically illustrated in FIG. 3a.

As it can be see from FIG. 3a, chips 2, 3, 4 and 1 are mounted in this order on printed circuit board (PCB) 5. Section 6 of printed circuit board 5 on which chips 2 and 3 are mounted is connected to section 7 of printed circuit board 8, on which chips 4 and 1 are mounted by means of flexible printed circuit board 9. Between chips 2 and 3, and 4 and 1 routing means or bonds 21 are provide in order to electrically connect chips 2,3,4 and 1. By folding flexible printed circuit board 9 at 180° in such a way that the top surface of chips 2/3 face the top surface of chips 1/4 it is possible to arrange chips 2/3, which form the first pair of chips in an anti-parallel manner with the chips 1 and 4 so that top surface 11 of chip 1 faces top surface 12 of chip 2. The same applies to top surfaces 13 of chip 3 and top surface 14 of chip 4 respectively.

Thereafter, heat sink 30 can be introduced in such a manner that a thermal connection between chips 1,2,3 and 4 with heat sink 30 can be established. By way of example it is also illustrated how printed circuit board 4 is arranged with balls 50.

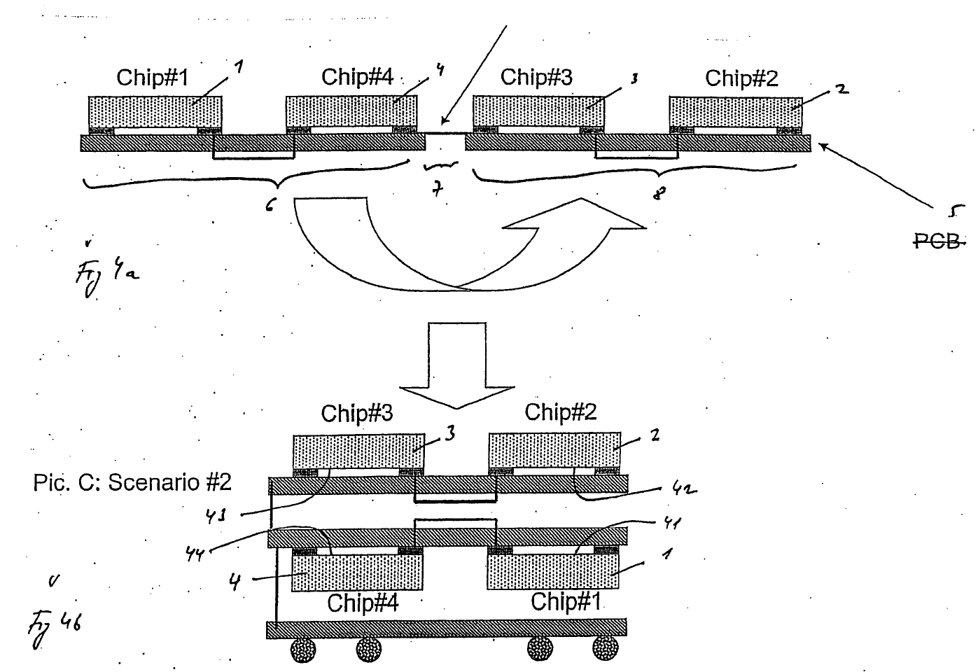

FIG. 4b illustrates another preferred embodiment of the present invention. In this embodiment chips 1,4,3, and 2 are arranged anti-parallel to each other and are facing outwards and so that it is possible to obtain an arrangement without having to provide a heat sink since the heat exchange between the chips and the ambient environment is possible.

A method of preparation of this embodiment is schematically illustrated in FIG. 4a. As it can be see from FIG. 4a, chips 1,4,3, and 2 are mounted in this order on printed circuit board (PCB) 50. Section 60 of printed circuit board 50 on which chips 2 and 3 are mounted is connected to section 70 of printed certain board 50, on which chips 4 and 1 are mounted by means of flexible printed circuit board 90. Between chips 2/3, and 4/1 routing means or bonds 21 are provide in order to electrically connect chips 1,4,3, and 2.

By folding flexible printed circuit board 90 at 180° in such a way that the bottom surfaces of chips 1/2, and 3/4 face each other it is possible to arrange chips 1 and 2, and 3 and 4 in an anti-parallel manner so that top surface 41 of chip 1 faces top surface 42 of chip 2. The same applies to top surfaces 13 of chip 3 and top surface 44 of chip 4 respectively. In this manner an subassembly 60 can be manufactured which can then be connected with a PCB with usual means.

Even though it is not absolutely necessary in this embodiment a heat sink (not illustrated) can also be introduced in such a manner that a thermal connection between chips 1/2 and/or 3/4 with the heat sink can be established.

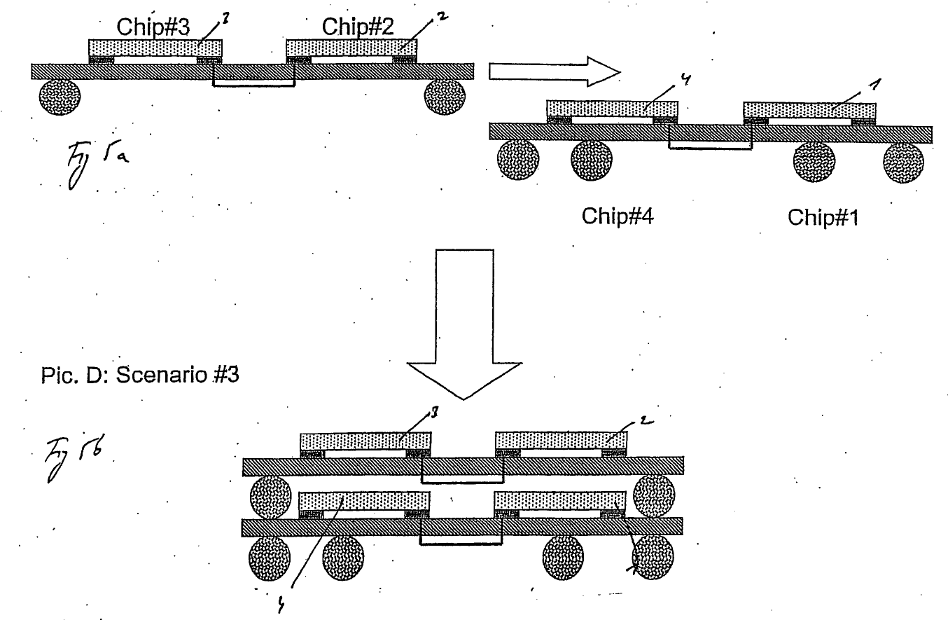

FIG. 5b illustrates another preferred embodiment of the present invention. In this embodiment chips 4/1 and 3/2 are arranged in a parallel manner. A method of preparation of this embodiment is schematically shown in FIG. 5a.

As it can be seen from FIG. 5a, chips 3 and 2 as well as chips 4 and 1 respectively are mounted separately on a printed circuit board. By means of ball grid arrays it is then possible to connect the printed board section on which chips 3/2 and 4/1 respectively are mounted.

While the invention has been described in terms of several (example) preferred embodiments, those skilled in the art will recognize that the invention can be practiced with modification within the spirit and scope of the appended claims.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A multi-chip package comprising:
at least four spaced semiconductor integrated circuit chips mounted on a printed circuit board, comprising:
a first pair of semiconductor integrated circuit chips; and
a second pair of semiconductor integrated circuit chips, wherein the chips of the first pair of semiconductor integrated circuit chips are arranged essentially parallel and the chips of the second pair of the semiconductor integrated circuit chips are arranged substantially stacked over the chips of the first pair of the semiconductor integrated circuit chips.

2. The multi-chip package according to claim 1, wherein a top surface of the chips of the second pair of the semiconductor integrated circuit chips faces a top surface of the chips of the first semiconductor integrated circuit chips.

3. The multi-chip package according to claim 1, wherein a bottom surface of the chips of the second pair of the semiconductor integrated circuit chips faces a bottom surface of the chips of the second pair of the semiconductor integrated circuit chips.

4. The multi-chip package according to claim 1, wherein the first pair of the semiconductor integrated circuit chips is mounted on a first section of the printed circuit board and the second pair of the semiconductor integrated circuit chips is mounted on a second section of the printed circuit board; and wherein the first and the second section of the printed circuit board are connected by a flexible printed circuit board.

5. The multi-chip package according to claim 1, further comprising a heat sink.

6. The multi-chip package according to claim 1, further comprising more than one heat sink.

7. The multi-chip package according to claim 5, wherein the heat sink is thermally connected to the first and/or to the second pair of the semiconductor integrated circuit chips.

8. The multi-chip package according to claim 5, wherein the heat sink is thermally connected to both the first and the second pair of the semiconductor integrated circuit chips.

9. The multi-chip package according to claim 6, wherein one of the heat sinks is thermally connected only to the first pair of the semiconductor integrated circuit chips.

10. The multi-chip package according to claim 6, wherein one of the heat sinks is thermally connected only to the second pair of the semiconductor integrated circuit chips.

11. The multi-chip package according to claim 1 wherein the semiconductor integrated circuit chips are connected with each other by means of wires.

12. The multi-chip package according to claim 1, wherein the printed circuit board is contacted by means of ball grid array.

13. A multi-chip arrangement comprising:
a printed circuit board having a first section and a second section;
a first pair of semiconductor chips mounted on the first section, and arranged in parallel; and
a second pair of semiconductor chips mounted on the second section, stacked over the first pair of semiconductor chips.

14. The chip arrangement of claim 13, comprising:
the printed circuit board having a third section, connecting the first section to the second section.

15. The chip arrangement of claim 14, comprising wherein the third section is a flexible section.

16. The chip arrangement of claim 13, comprising wherein the first section is connected to the second section via a ball grid array.

17. The chip arrangement of claim 13, comprising wherein the first section is parallel to the second section.

18. The chip arrangement of claim 13, comprising wherein the first section is anti-parallel to the second section.

19. A multi-chip arrangement including a first chip, a second chip, a third chip, and a fourth chip comprising:
a printed circuit board having a first section, a second section, and a flexible section;
a first pair of semiconductor chips mounted comprising the first chip and the fourth ship, mounted on the first section; and
a second pair of semiconductor chips comprising the second chip and the third chip, mounted on the second section, stacked over the first pair of semiconductor chips in an anti-parallel arrangement with the first pair of semiconductor chips.

20. The multi-chip arrangement of claim 19 comprising:
a first heat sink positioned between the first chip and the fourth chip; and
a second heat sink positioned between the second chip and the third chip.

21. The multi-chip arrangement of claim 19, comprising:
wherein the first section is positioned adjacent the second section.

22. The multi-chip arrangement of claim 19, comprising:
wherein the printed circuit board includes a fourth section coupled to the second section; and
a ball grid array coupled to the fourth section.

23. The multi-chip arrangement of claim 19, comprising:
a heat sink; and
wherein the first chip, the second ship, the third chip and the fourth chip each have a top surface facing the heat sink.

24. The multi-chip arrangement of claim 23, comprising:
a ball grid array coupled to the first section.

25. The multi-chip arrangement of claim 19, comprising:
a plurality of chip pads, wherein the first chip and the fourth chip are coupled to the first section via one or more chip pads.

26. A method of making a multi-chip package comprising:
defining a printed circuit board having a first section, a second section, and a flexible section;
mounting a first pair of semiconductor chips on the first section;
mounting a second pair of semiconductor chips on the second section;
coupling the first section to the second section via the flexible section; and
folding the first section relative to the second section, via the flexible section, such that the first pair of semiconductor chips is configured anti-parallel to the second pair of semiconductor chips.

27. The method of claim 26 comprising:
providing a heat sink between the first pair of semiconductor chips and the second pair of semiconductor chips.

28. The method of claim 26 comprising:
wherein folding includes positioning the first section immediately adjacent the second section, having the first pair of semiconductor chips and the second pair of semiconductor chips facing outward relative to the first section and the second section.

29. A multi-chip package comprising:
means for providing a printed circuit board having a first section and a second section;
means for providing a first pair of semiconductor chips mounted on the first section, and arranged in parallel; and
means for providing a second pair of semiconductor chips mounted on the second section, stacked over the first pair of semiconductor chips and arranged anti-parallel to the first pair of semiconductor chips.
